(19) United States
(12) Patent Application Publication
(10) Pub. No.: US 2021/0255544 A1
(43) Pub. Date: Aug. 19, 2021

(54) RESIST COMPOSITION

(71) Applicant: SAMSUNG ELECTRONICS CO., LTD., Suwon-si (KR)

(72) Inventors: Yechan KIM, Hwaseong-si (KR); Suk Koo HONG, Suwon-si (KR); Su Min KIM, Suwon-si (KR); Ju-Young KIM, Hwaseong-si (KR); Jinjoo KIM, Seoul (KR); Hyunwoo KIM, Seongnam-si (KR); Juhyeon PARK, Suwon-si (KR); Hyunji SONG, Suwon-si (KR); Songse YI, Seoul (KR)

(21) Appl. No.: 17/003,414

(22) Filed: Aug. 26, 2020

(30) Foreign Application Priority Data
Feb. 6, 2020 (KR) 10-2020-0014452

(51) Int. Cl. G03F 7/004; G03F 7/038; G03F 7/039

(52) U.S. Cl. CPC G03F 7/0045; G03F 7/039; G03F 7/038

(57) ABSTRACT

A resist composition including a polymer; a photoacid generator; and a material represented by Formula 1:

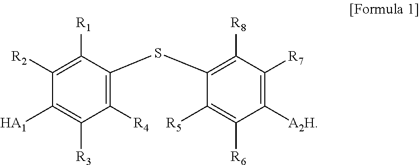

### CROSS-REFERENCE TO RELATED APPLICATION

Korean Patent Application No. 10-2020-0014452, filed on Feb. 6, 2020, in the Korean Intellectual Property Office, and entitled: “Resist Composition,” is incorporated by reference herein in its entirety.

### BACKGROUND

### 1. Field

Embodiments relate to a resist composition.

### 2. Description of the Related Art

Semiconductor devices are highly integrated and reliable in order to satisfy consumers' demand for excellent performance and an affordable price. The higher level of integration of semiconductor devices may require more precise patterning in a manufacturing process of semiconductor devices. Patterning of an etching target film may be performed by an exposure process and a development process using a photoresist film.

### SUMMARY

The embodiments may be realized by providing a resist composition including a polymer; a photoacid generator; and a material represented by Formula 1:

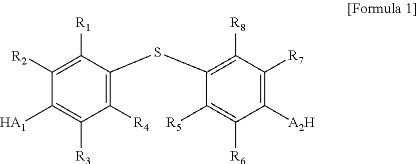

wherein in Formula 1, R₁, R₂, R₃, R₄, R₅, R₆, R₇, and R₈ are each independently hydrogen, a halogen, a substituted or unsubstituted alkyl group having 1 to 7 carbon atoms, a substituted or unsubstituted carbonyl group having 1 to 7 carbon atoms, a substituted or unsubstituted ester group having 1 to 7 carbon atoms, a substituted or unsubstituted acetal group having 1 to 7 carbon atoms, a substituted or unsubstituted alkoxy group having 1 to 7 carbon atoms, or a substituted or unsubstituted ether group having 1 to 7 carbon atoms, and A₁ and A₂ are each independently O or S.

The embodiments may be realized by providing a composition including a polymer; a photoacid generator; a quencher; and a material represented by Formula 1A:

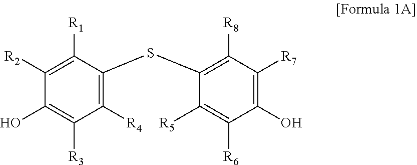

wherein, in Formula 1A, R₁, R₂, R₃, R₄, R₅, R₆, R₇, and R₈ are each independently hydrogen, a halogen, a substituted or unsubstituted alkyl group having 1 to 7 carbon atoms, a substituted or unsubstituted carbonyl group having 1 to 7 carbon atoms, a substituted or unsubstituted ester group having 1 to 7 carbon atoms, a substituted or unsubstituted acetal group having 1 to 7 carbon atoms, a substituted or unsubstituted alkoxy group having 1 to 7 carbon atoms, or a substituted or unsubstituted ether group having 1 to 7 carbon atoms.

The embodiments may be realized by providing a composition including a polymer; a photoacid generator; a quencher; and a material represented by Formula A,

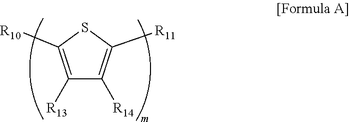

wherein, in Formula A, R₁₀ and R₁₁ are each independently hydrogen, a halogen, a substituted or unsubstituted alkyl group having 1 to 5 carbon atoms, a substituted or unsubstituted cyclic compound having 5 to 10 carbon atoms, a substituted or unsubstituted carbonyl group having 1 to 5 carbon atoms, a substituted or unsubstituted ester groups having 1 to 5 carbon atoms, a substituted or unsubstituted acetal groups having 1 to 5 carbon atoms, a substituted or unsubstituted alkoxy groups having 1 to 5 carbon atoms, a substituted or unsubstituted ether group having 1 to 5 carbon atoms, —SO₃H, or —NO₂, R₁₃ and R₁₄ are each independently hydrogen, a halogen, a substituted or unsubstituted alkyl group having 1 to 5 carbon atoms, a substituted or unsubstituted cyclic compound having 5 to 10 carbon atoms, —SO₃H, or —NO₂, R₁₃ and R₁₄ being separate or bonded to each other to form a ring, and m is an integer of 1 to 5.

### BRIEF DESCRIPTION OF THE DRAWINGS

Features will be apparent to those of skill in the art by describing in detail exemplary embodiments with reference to the attached drawings in which:

FIG. 1A is a plan view illustrating a resist pattern according to an embodiment;

FIG. 1B is a plan view illustrating a resist pattern according to an embodiment;

FIGS. 2 to 6 are views of stages in a method of manufacturing a semiconductor device according to embodiments; and

FIGS. 7 and 8 are views of stages in a method of manufacturing a semiconductor device according to other embodiments.

### DETAILED DESCRIPTION

In the present description, unless otherwise specified, the carbonyl group may be a substituted or unsubstituted carbonyl group. The ester group may be a substituted or unsubstituted ester group. The acetal group may be a substituted or unsubstituted acetal group. The alkoxy group may be a substituted or unsubstituted alkoxy group. The ether group may be a substituted or unsubstituted ether group.

In the present description, the description of a group being bonded to an adjacent group to form a ring may indicate that one is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by being bonded to each other may be connected to another ring to form a spiro structure.

In the present description, the alkyl group may be a linear alkyl group, a branched alkyl group, or a cyclic alkyl group. The alkyl group may include primary alkyl, secondary alkyl, and tertiary alkyl. The number of carbon atoms in the alkyl group is not particularly limited, but may be 1 to 7, and specifically 1 to 5. As used herein, the term “or” is not an exclusive term, e.g., “A or B” would include A, B, or A and B.

In the present description, the alkyl groups of an alkyl sulfonate group, an alkyl thio group, an alkyl sulfoxy group, an alkyl carbonyl group, an alkyl ester group, an alkyl ether group, and an alkyl acetal group are the same as examples of the above-described alkyl group. In the present description, a halogen (e.g., a halogen element) may include fluorine, chlorine, iodine, or bromine.

Unless otherwise defined in Formulae of the present description, when a chemical bond is not drawn at a position where the chemical bond is supposed to be drawn, it may mean that a hydrogen atom is bonded at the position.

In the present description, like reference numerals may refer to like elements throughout.

Hereinafter, a composition according to embodiments, a method of forming a pattern using the composition, and a method of manufacturing a semiconductor device will be described.

According to an embodiment, the composition may be a resist composition. The composition may be used for forming a pattern or manufacturing a semiconductor device. In an implementation, the resist composition may be used in a patterning process for manufacturing a semiconductor device. The resist composition may be an extreme ultraviolet (EUV) resist composition. The extreme ultraviolet may mean ultraviolet rays having a wavelength of about 13.0 nm to about 13.9 nm, e.g., a wavelength of about 13.4 nm to about 13.6 nm. The extreme ultraviolet may mean light having an energy of about 90 eV to about 95 eV. In an implementation, the resist composition may be used in an exposure process using argon fluoride (hereinafter, ArF) as a light source. The light source using ArF may emit light having a wavelength of about 185 nm to about 200 nm, e.g., about 190 m to about 195 nm. The resist composition may be a chemically amplified resists type (CAR type) resist composition.

In an implementation, the resist composition may include, e.g., a polymer, a photoacid generator, a quencher, and a photosensitizer. In an implementation, the photosensitizer may include a material represented by Formula 1 or Formula A below.

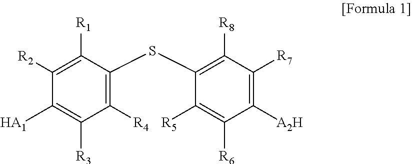

In Formula 1, R₁, R₂, R₃, R₄, R₅, R₆, R₇, and R₈ may each independently be or include, e.g., hydrogen, a halogen, a substituted or unsubstituted alkyl group having 1 to 7 carbon atoms, a substituted or unsubstituted carbonyl group having 1 to 7 carbon atoms, a substituted or unsubstituted ester group having 1 to 7 carbon atoms, a substituted or unsubstituted acetal group having 1 to 7 carbon atoms, a substituted or unsubstituted alkoxy group having 1 to 7 carbon atoms, or a substituted or unsubstituted ether group having 1 to 7 carbon atoms. A₁ and A₂ may each independently be, e.g., O or S.

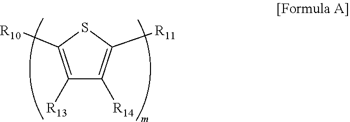

In Formula A, R₁₀ and R₁₁ may each independently be or include, e.g., hydrogen, a halogen, a substituted or unsubstituted alkyl group having 1 to 5 carbon atoms, a substituted or unsubstituted cyclic compound having 5 to 10 carbon atoms, a substituted or unsubstituted carbonyl group having 1 to 5 carbon atoms, a substituted or unsubstituted ester groups having 1 to 5 carbon atoms, a substituted or unsubstituted acetal groups having 1 to 5 carbon atoms, a substituted or unsubstituted alkoxy groups having 1 to 5 carbon atoms, a substituted or unsubstituted ether group having 1 to 5 carbon atoms, —SO₃H, or —NO₂. R₁₃ and R₁₄ may each independently be or include, e.g., hydrogen, a halogen, a substituted or unsubstituted alkyl group having 1 to 5 carbon atoms, a substituted or unsubstituted cyclic compound having 5 to 10 carbon atoms, —SO₃H, or —NO₂. In an implementation, R₁₃ and R₁₄ may be separate, or may be bonded to each other to form a ring (e.g., having 1 to 10 carbon atoms). m may be, e.g., an integer of 1 to 5.

In an implementation, in Formula A, when R₁₀ and R₁₁ are cyclic compounds, the cyclic compounds may be substituted or unsubstituted aromatic ring compounds. In an implementation, R₁₀ and R₁₁ may be bonded to each other to form a benzene ring.

In an implementation, in Formula A, R₁₃ and R₁₄ may be bonded to each other to form a ring. In an implementation, the ring may be a heterocycle having 1 to 5 carbon atoms. In an implementation, R₁₃ and R₁₄ may be bonded to each other via —O—(CH₂)ₓ—O—, in which x is an integer of 1 to 5.

In an implementation, in Formula A, the ester group may be —OOCR₄₀ or —COOR₄₀, the acetal group may be —CR₄₁(OR₄₂)(OR₄₃), the ether group may be —OR₄₄, the carbonyl group may be —COR₄₅. R₄₀, R₄₁, R₄₂, R₄₃, and R₄₅ may each independently be, e.g., an alkyl group having 1 to 4 carbon atoms, and R₄₄ may be, e.g., an alkyl group having 1 to 5 carbon atoms. A total number of carbon atoms of R₄₁, R₄₂, and R₄₃ may be 5 or less.

In an implementation, the polymer may be a photoresist material. In an implementation, the polymer may include a polymerized unit represented by Formula 2A and a polymerized unit represented by Formula 2B. The polymerized unit represented by Formula 2B may be linked to the polymerized unit represented by Formula 2A.

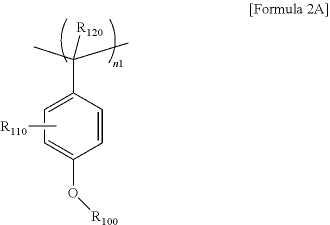

In Formula 2A, R₁₀₀, R₁₁₀, and R₁₂₀ may each independently be or include, e.g., hydrogen or a substituted or unsubstituted alkyl group having 1 to 7 carbon atoms. n1 may be, e.g., an integer of 1 to 1,000,000.

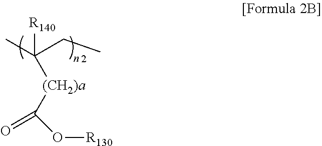

In Formula 2B, R₁₃₀ may be or may include, e.g., a substituted or unsubstituted tertiary alkyl group having 4 to 20 carbon atoms. R₁₄₀ may be or may include, e.g., hydrogen or a substituted or unsubstituted alkyl group having 1 to 7 carbon atoms. a may be, e.g., an integer of 0 to 5. n2 may be, e.g., an integer of 1 to 1,000,000.

In Formulae 2A and 2B, n1+n2 may be an integer of 50 to 1,000,001, e.g., 50 to 1,000,000.

In an implementation, in Formula 2B, R₁₃₀ may be, e.g., a substituted or unsubstituted cyclic tertiary alkyl group having 4 to 20 carbon atoms.

In an implementation, the polymer may include polyhydroxystyrene (PHS). In an implementation, the polymerized unit represented by Formula 2A may be polyhydroxystyrene (PHS).

In an implementation, the photoacid generator may generate hydrogen ions (W) in an exposure process of a resist film. The photoacid generator may include a material represented by Formula 3 or a material represented by Formula 4 below.

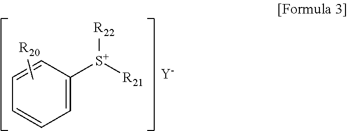

In Formula 3, R₂₀ may be or may include, e.g., hydrogen or a substituted or unsubstituted alkyl group having 1 to 5 carbon atoms. R₂₁ and R₂₂ may each independently be or include, e.g., an alkyl group having 1 to 7 carbon atoms or a substituted or unsubstituted aromatic ring compound having 4 to 20 carbon atoms. Y may be, e.g., a conjugate base of strong acid.

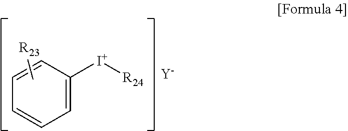

In Formula 4, R₂₃ may be or may include, e.g., hydrogen or a substituted or unsubstituted alkyl group having 1 to 5 carbon atoms. R₂₄ may be or may include, e.g., an alkyl group having 1 to 7 carbon atoms or a substituted or unsubstituted aromatic ring compound having 4 to 20 carbon atoms. Y may be, e.g., a conjugate base of strong acid.

In an implementation, the material represented by Formula 3 may include a material represented by Formula 3A below.

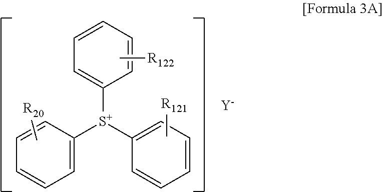

In Formula 3A, R₂₀, R₁₂₁, and R₁₂₂ may each independently be or include, e.g., hydrogen or a substituted or unsubstituted alkyl group having 1 to 5 carbon atoms, and Y may be the same as defined in Formula 3.

In an implementation, the material represented by Formula 4 may include a material represented by Formula 4A below.

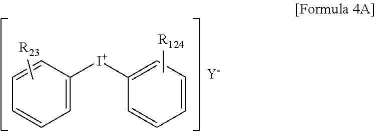

In Formula 4A, R₂₃ and R₁₂₄ may each independently be or include, e.g., hydrogen or a substituted or unsubstituted alkyl group having 1 to 5 carbon atoms, and Y may be the same as defined in Formula 4.

In an implementation, in Formulae 3 and 4, Y may include, e.g., a sulfonate group or moiety having 1 to 10 carbon atoms. In an implementation, in Formulae 3 and 4, Y may include, e.g., a material represented by Formula Y below.

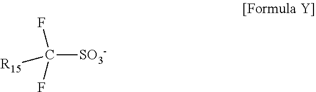

In Formula Y, R₁₅ may be or may include, e.g., hydrogen, a halogen, or a substituted or unsubstituted alkyl group having 1 to 5 carbon atoms.

In an implementation, in Formula Y, R₁₅ may be, e.g., fluorine or iodine.

The quencher may be a photo decomposable quencher (PDQ). In an implementation, the quencher may include a material represented by Formula 5 or a material represented by Formula 6 below.

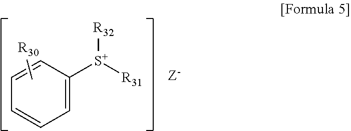

In Formula 5, R₃₀ may be or may include, e.g., hydrogen or a substituted or unsubstituted alkyl group having 1 to 5 carbon atoms. R₃₁ and R₃₂ may each independently be or include, e.g., an alkyl group having 1 to 7 carbon atoms or a substituted or unsubstituted aromatic ring compound having 4 to 20 carbon atoms. Z may be, e.g., a conjugate base of weak acid.

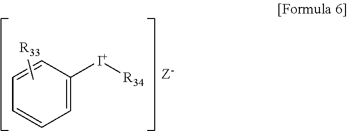

In Formula 6, R₃₃ may be or may include, e.g., hydrogen or a substituted or unsubstituted alkyl group having 1 to 5 carbon atoms. R₃₄ may be or may include, e.g., an alkyl group having 1 to 7 carbon atoms or a substituted or unsubstituted aromatic ring compound having 4 to 20 carbon atoms. Z may be, e.g., a conjugate base of weak acid.

In an implementation, the material represented by Formula 5 may include a material represented by Formula 5A below.

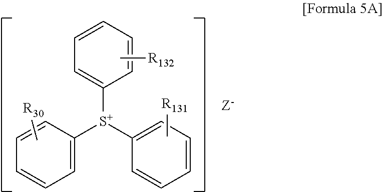

In Formula 5A, R₃₀, R₁₃₁, and R₁₃₂ may each independently be or include, e.g., hydrogen or a substituted or unsubstituted alkyl group having 1 to 5 carbon atoms. Z may be the same as defined in Formula 5.

In an implementation, the material represented by Formula 6 may include a material represented by Formula 6A below.

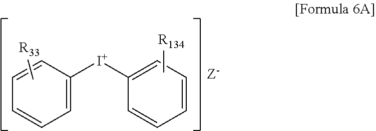

In Formula 6A, R₃₃ and R₁₃₄ may each independently be or include, e.g., hydrogen or a substituted or unsubstituted alkyl group having 1 to 5 carbon atoms. Z may be the same as defined in Formula 6.

In an implementation, in Formulae 5 and 6, Z may include, e.g., a carboxylate group or moiety having 1 to 10 carbon atoms. In an implementation, in Formulae 5 and 6, Z may include, e.g., a material represented by Formula Z below.

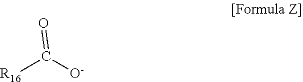

In Formula Z, R₁₆ may be or may include, e.g., hydrogen, a halogen, or a substituted or unsubstituted alkyl group having 1 to 5 carbon atoms.

The resist composition may further include an organic solvent. The organic solvent may be a non-polar solvent. The organic solvent may include, e.g., propylene glycol methyl ether acetate (1-methoxy-2-propyl acetate, PGMEA), propylene glycol methyl ether (1-methoxy-2-propanol, PGME), ethylene glycol (ethane-1,2-diol, EL), gamma-butyrolactone (GBA), or diacetone alcohol (DAA). The photosensitizer may have high solubility in the organic solvent. The resist composition may be prepared by dissolving the polymer, photoacid generator, quencher, and photosensitizer in the organic solvent.

Hereinafter, the material represented by Formula 1 according to an embodiment and an exposure process of a resist composition will be described in more detail.

In an implementation, the material represented by Formula 1 may include a material represented by Formula 1A below. The material represented by Formula 1A may include 4,4′-thiodiphenol and its derivatives.

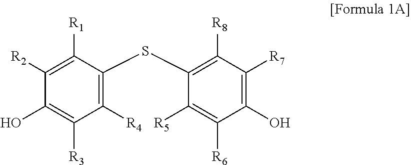

In Formula 1A, R₁, R₂, R₃, R₄, R₅, R₆, R₇, and R₈ may each independently be or include, e.g., hydrogen, a halogen, a substituted or unsubstituted alkyl group having 1 to 7 carbon atoms, a substituted or unsubstituted carbonyl group having 1 to 7 carbon atoms, a substituted or unsubstituted ester group having 1 to 7 carbon atoms, a substituted or unsubstituted acetal group having 1 to 7 carbon atoms, a substituted or unsubstituted alkoxy group having 1 to 7 carbon atoms, or a substituted or unsubstituted ether group having 1 to 7 carbon atoms.

In an implementation, in Formulae 1 and 1A, the ester group may be —OOCR₅₀ or —COOR₅₀, the acetal group may be —CR₅₁(OR₅₂)(OR₅₃), the ether group may be —OR₅₄, the carbonyl group may be —COR₅₅, R₅₀, R₅₁, R₅₂, R₅₃, and R₅₅ may each independently be or include, e.g., an alkyl group having 1 to 6 carbon atoms, and R₅₄ may be or may include, e.g., an alkyl group having 1 to 7 carbon atoms. A total number of carbon atoms of R₅₁, R₅₂, and R₅₃ may be 7 or less.

The material represented by Formula 1 may have a high highest occupied molecular orbital (hereinafter, HOMO) energy level. During an exposure process of a resist film, a polymer absorbs photons of light to emit electrons and hydrogen ions (W), and may form a polymer having a modified structure. The light may be extreme ultraviolet. In an implementation, the polymerized unit represented by Formula 2A of the polymer may absorb photons of light to emit electrons and hydrogen ions. The electron and hydrogen ion emission reaction of the polymer according to an embodiment may be performed as shown in Reaction Formula 1 below.

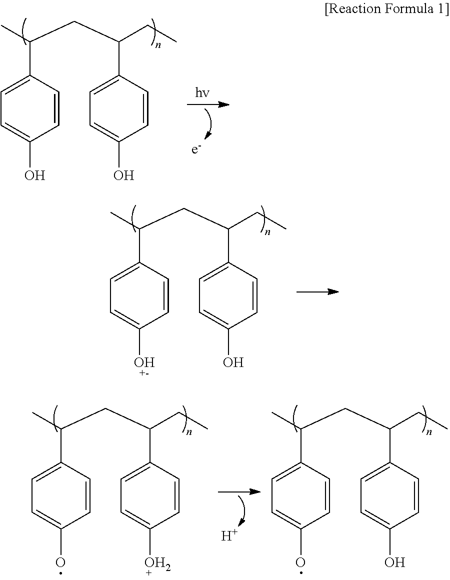

The polymerized unit represented by Formula 2B of the polymer may react with the generated electrons or hydrogen ions to form a polymer having a modified structure. In an implementation, the ester group of the polymerized unit represented by Formula 2B may react with hydrogen ions to form a carboxylic acid. The carboxylic acid forming reaction may be referred to as a deprotection reaction. The polymerized unit in which the carboxylic acid is formed may be a polymer having a modified structure, and the exposed portion of the resist film may include a polymer having a modified structure.

The photoacid generator may generate hydrogen ions by photons of light. The hydrogen ion generation from the photoacid generator may be performed as shown in Reaction Formula 2 below. The hydrogen ions generated from the photoacid generator may promote the formation of a modified polymer.

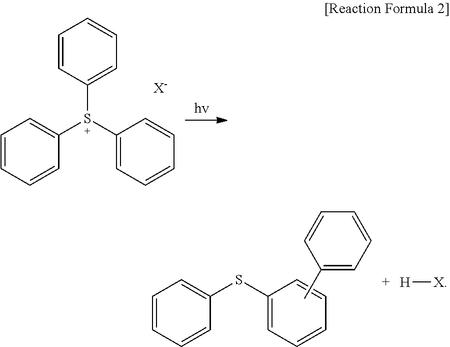

In Reaction Formula 2, X may be the same as defined in Formula 3.

Extreme ultraviolet has high energy per photon, and may have a smaller number of photons at the same exposure amount than light in the KrF exposure process. If the photosensitizer were to be omitted, the deprotection reaction efficiency of the polymer may be reduced due to the small number of photons. It may be difficult to sufficiently form a modified polymer in the exposed portion of the resist film. Due to the photon shot noise effect, the resist pattern may have a relatively larger line width roughness.

According to embodiments, the photosensitizer may have a high HOMO energy level and a low ionization potential. Accordingly, the photosensitizer may be easily activated even with a small number of photons to generate secondary electrons and hydrogen ions. The secondary electron and hydrogen ion generation reaction of the photosensitizer according to an embodiment may be performed as shown in Reaction Formula 3 below. The deprotection reaction efficiency of a polymer may be improved.

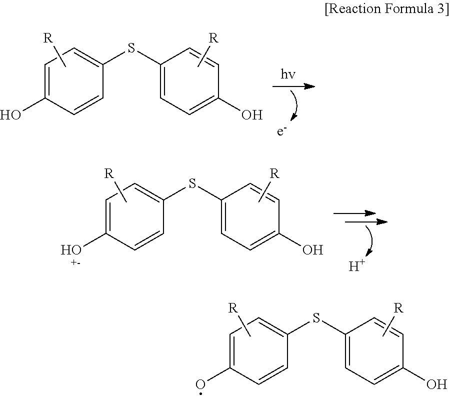

In an implementation, the resist composition may include the photosensitizer, thereby increasing the deprotection reaction efficiency of the polymer, and preventing the photon shot effect. Accordingly, the efficiency and accuracy of an exposure process may be improved. In an implementation, the resist pattern may be formed with high accuracy and have a fine pitch. Line width roughness of the formed resist pattern may be reduced.

In an implementation, the material represented by Formula 1A may include a material represented by Formula 1-1, Formula 1-2, Formula 1-3, or Formula 1-4 below.

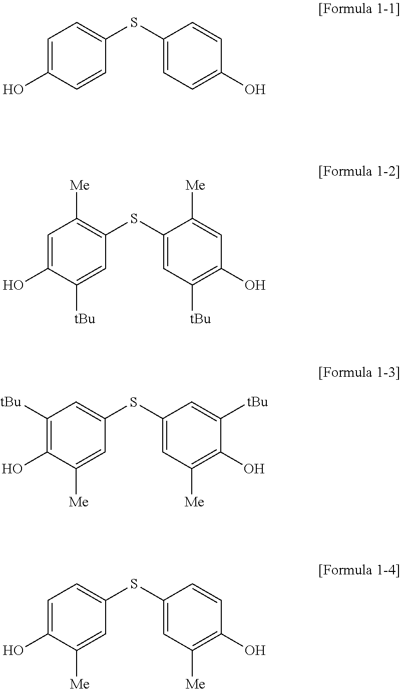 [SMILES: Oc1ccc(Sc2ccc(O)cc2)cc1 ; Cc1cc(O)c(C(C)(C)C)cc1Sc1cc(C(C)(C)C)c(O)cc1C ; Cc1cc(Sc2cc(C)c(O)c(C(C)(C)C)c2)cc(C(C)(C)C)c1O ; Cc1cc(Sc2ccc(O)c(C)c2)ccc1O]

In Formulae 1-2, 1-3, and 1-4, Me is methyl and tBu is tert-Butyl.

The material represented by Formula 1-1 may be referred to as 4,4′-thiodiphenol, and the material represented by Formula 1-2 may be referred to as 4,4′-thiobis(6-tert-butyl-m-cresol), the material represented by Formula 1-3 may be referred to as 4,4′-thiobis(6-tert-butyl-o-cresol), and the material represented by Formula 1-4 may be referred to as bis(4-hydroxy-3-methylphenyl) sulfide.

In an implementation, the photosensitizer may be prepared as shown in Reaction Formula A.

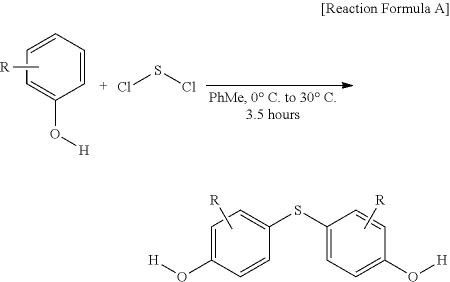

In Reaction Formula A, PhMe is toluene, and R may be any one of the exemplary groups of R₁ in Formula 1.

Table 1 shows HOMO energy levels of materials represented by Formulas 1-1, 1-2, 1-3, and 1-4, and a polymer according to an embodiment.

TABLE 1

| | | HOMO energy |
|---|---|---|
| | Compound | level (eV) |
| Polymer | Polyhydroxystyrene | −8.91 |
| Example | Material represented by Formula 1-1 | −7.07 |
| | Material represented by Formula 1-2 | −6.80 |
| | Material represented by Formula 1-3 | −6.82 |
| | Material represented by Formula 1-4 | −6.92 |

Referring to Table 1, materials represented by Formulas 1-1, 1-2, 1-3, and 1-4 have higher HOMO energy levels than polyhydroxystyrene. The photosensitizer may have a higher HOMO energy level than the polymerized unit represented by Formula 2A (e.g., polyhydroxystyrene). In an implementation, the photosensitizer may have a HOMO energy level higher than −8.50 eV. Accordingly, the photosensitizer may be easily activated to generate secondary electrons and hydrogen ions with high efficiency. If the photosensitizer were to have a lower HOMO energy level than the polymer (e.g., less than −8.50 eV), it may be difficult to sufficiently improve the deprotection reaction of the polymer.

In an implementation, the material represented by Formula 1 may include two 4, 4′-thoibenzene groups. Even when electrons or hydrogen ions are generated at —SH or —OH substituted at the 4-position of a benzene ring to generate a radical or anion, the radical or anion may be stabilized by resonance structure. Accordingly, the material represented by Formula 1 may easily generate secondary electrons or hydrogen ions.

In an implementation, in Formula 1, at least one of R₁, R₂, R₃, R₄, R₅, R₆, R₇, and R₈ may include a halogen, an alkyl group, an ester group, an acetal group, an alkoxy group, or an ether group. Depending on the type and position of a functional group substituted on the benzene ring of Formula 1, the stability of ionization potential, pKa, and radicals of the material represented by Formula 1 may be controlled. By controlling the type and position of the functional group substituted on the benzene ring of Formula 1, the deprotection reaction efficiency of the polymer may be further improved.

In an implementation, in Formula 1, at least one of R₁, R₂, R₃, R₄, R₅, R₆, R₇, and R₈ may include a halogen. The halogen may include fluorine, chlorine, bromine, and iodine. In an implementation, at least one of R₁ to R₈ may include fluorine or iodine. Fluorine and iodine may have excellent extreme ultraviolet absorption properties. When the material represented by Formula 1 includes fluorine or iodine, absorption characteristics in photons of enhanced extreme ultraviolet and high generation efficiency for secondary electrons or hydrogen ions may be achieved.

Hereinafter, the material represented by Formula A will be described in detail. Repeated descriptions may be omitted.

In an implementation, the material represented by Formula A may be thiophene or a derivative thereof. The material represented by Formula A may include, e.g., a material represented by one of Formulae A-1 to A-14 below.

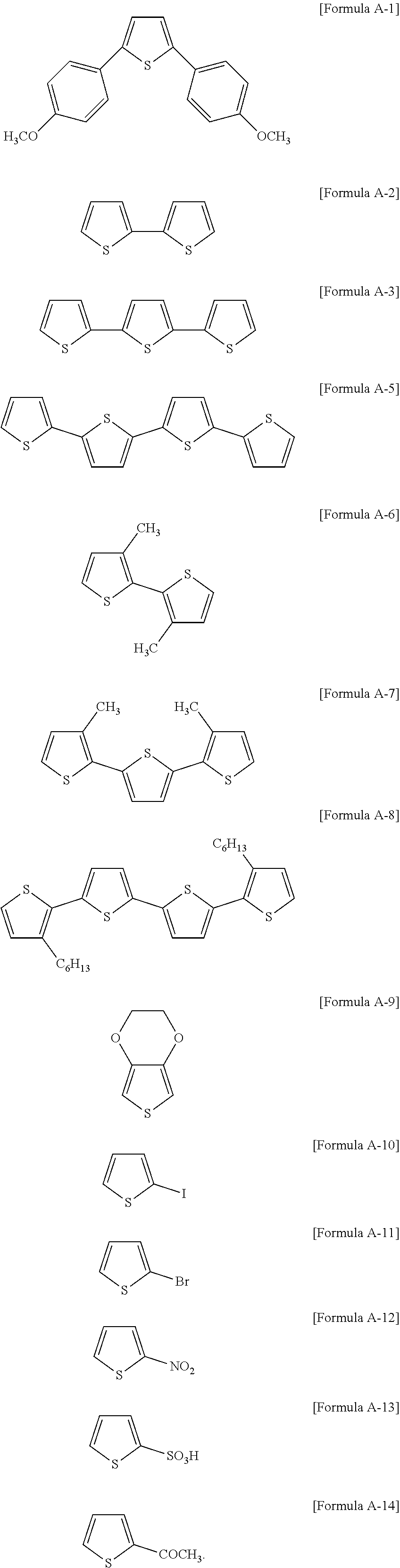

The material represented by Formula A-1 may be referred to as 2,5-bis(4-methoxyphenyl)thiophene, the material represented by Formula A-2 may be referred to as 2,2′:5′,2″-terthiophene or α-terthienyl, and the material represented by Formula A-3 may be referred to as 2,2′:5′, 2″:5″,2″′-quaterthiophene or α-quarterthienyl.

In an implementation, the materials represented by Formulas A-10 to A-14 may be prepared as shown in Reaction Formula 4 below.

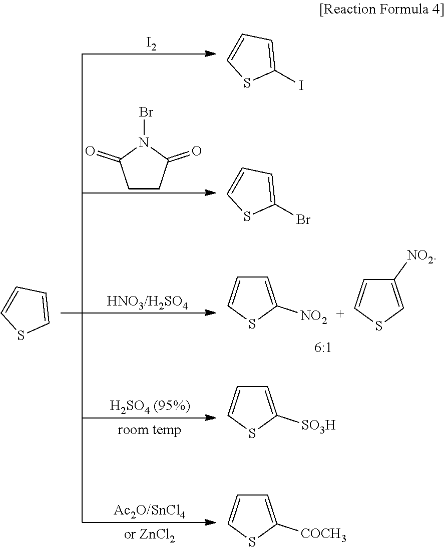

In Reaction Formula 4, room temperature indicates that the reaction proceeds at about 25° C., and Ac refers to CH₃CO.

Table 2 shows HOMO energy levels of materials represented by Formulas A-1, A-2, and A-3.

TABLE 2

| | | HOMO energy |
|---|---|---|
| | Compound | level (eV) |
| Example | Material represented by Formula A-1 | −6.66 |
| | Material represented by Formula A-2 | −6.47 |
| | Material represented by Formula A-3 | −6.50 |

Referring to Table 2 along with Table 1, the HOMO energy levels of the materials represented by Formulas A-1, A-2, and A-3 may be greater than the HOMO energy level of polyhydroxystyrene. The HOMO energy level of the photosensitizer represented by Formula A may be greater than the HOMO energy level of the polymer, e.g., the HOMO energy level of the polymerized unit represented by Formula 2A. In an implementation, the HOMO energy level of the photosensitizer represented by Formula A may be greater than −8.50 eV. The photosensitizer may be easily activated to generate secondary electrons and hydrogen ions with high efficiency.

In an implementation, the material represented by Formula A may be non-conductive, and may have a conjugation structure by 7c-orbital overlap. After emitting secondary electrons, radicals may be formed in the material represented by Formula A. The radicals may be stabilized by the conjugation structure. The material represented by Formula A may easily generate secondary electrons or hydrogen ions by photons of light. The material represented by Formula A may extend life of the generated secondary electrons. The secondary electrons may be secondary electrons generated from a photosensitizer or a polymer.

The photosensitizer may interact well with a polymer to have high compatibility with the polymer. In an implementation, depending on the type and position of a functional group substituted on a thiophene ring of Formula A (e.g., in Formula A, R₂₁, R₂₂, R₂₃, or R₂₄), compatibility between the material represented by Formula A and the polymer may be controlled.

If the resist composition were to not include a material represented by Formula 1 or Formula A, and when 4,4′-thiodiphenol, thiophene or a derivative thereof is bonded to a polymerized unit of the polymer, the resist pattern formation efficiency may be reduced. For example, electrons and hydrogen ions emitted from the polymer in an exposure process may be reduced, or formation of a polymer having a modified structure may be reduced. According to embodiments, the resist composition may include a photosensitizer, and the photosensitizer may not be chemically bound to the polymer. In an implementation, the material represented by Formula 1 or Formula A may be provided in the resist composition in a single molecule state. Accordingly, the resist film formed using the resist composition may have high sensitivity to light. The formation efficiency of the resist pattern may be improved.

The following Experimental Examples and Comparative Examples are provided in order to highlight characteristics of one or more embodiments, but it will be understood that the Experimental Examples and Comparative Examples are not to be construed as limiting the scope of the embodiments, nor are the Comparative Examples to be construed as being outside the scope of the embodiments. Further, it will be understood that the embodiments are not limited to the particular details described in the Experimental Examples and Comparative Examples.

### Comparative Example 1

Polyhydroxystyrene (hereinafter referred to as PHS), a photoacid generator, a quencher, and a dye were mixed to prepare a resist composition. The resist composition is applied on a substrate to form a resist film. Irradiation of extreme ultraviolet was performed on the resist film to observe change in color of the resist film. Based on the degree to which the color of the resist film was changed, the amount of hydrogen ions generated was calculated.

### Comparative Example 2

PHS, a photoacid generator, a quencher, a dye, and a material represented by Formula 1-5 below were mixed to prepare a resist composition. Using the resist composition, a resist film was prepared in the same manner as in Comparative Example 1. Irradiation of extreme ultraviolet was performed on the resist film to calculate the amount of hydrogen ions generated based on the degree to which the color of the resist film was changed. Acid generation efficiency was obtained by calculating (the amount of hydrogen ions generated in Comparative Example 2)/(the amount of hydrogen ions generated in Comparative Example 1).

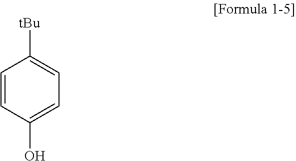 [SMILES: CC(C)(C)c1ccc(O)cc1]

In Formula 1-5, tBu is tert-Butyl.

### Experimental Example 1

PHS, a photoacid generator, a quencher, a dye, and a material represented by Formula 1-1 were mixed to prepare a resist composition. Using the resist composition, a resist film was prepared in the same manner as in Comparative Example 1. Irradiation of extreme ultraviolet was performed on the resist film to calculate the amount of hydrogen ions generated based on the degree to which the color of the resist film is changed. Acid generation efficiency was obtained by calculating (the amount of hydrogen ions generated in Experimental Example 1)/(the amount of hydrogen ions generated in Comparative Example 1).

### Experimental Example 2

PHS, a photoacid generator, a matting agent, a dye, and a material represented by Formula 1-2 were mixed to prepare a resist composition. Using the resist composition, a resist film was prepared in the same manner as in Comparative Example 1. Irradiation of extreme ultraviolet was performed on the resist film to calculate the amount of hydrogen ions generated based on the degree to which the color of the resist film is changed. Acid generation efficiency was obtained by calculating (the amount of hydrogen ions generated in Experimental Example 2)/(the amount of hydrogen ions generated in Comparative Example 1)

TABLE 3

| | Type of additive | Acid generation |
|---|---|---|
| | in composition | efficiency |
| Comparative | None | 1.00 |
| Example 1 | | |
| Comparative | Material represented | 1.10 |
| Example 2 | by Formula 1-5 | |
| Experimental | Material represented | 1.25 |
| Example 1 | by Formula 1-1 | |
| Experimental | Material represented | 1.25 |
| Example 2 | by Formula 1-2 | |

Referring to Table 3, Experimental Examples 1 and 2 had higher acid generation efficiency than the Comparative Examples. For example, the acid generation efficiencies of Experimental Examples 1 and 2 were approximately 25% higher than the acid generation efficiency of Comparative Example 1. According to embodiments, the materials represented by Formulas 1-1 and 1-2 may have high hydrogen ion generation efficiency in an exposure process.

Hereinafter, a method of forming a pattern using a resist compound according to embodiments and a method of manufacturing a semiconductor device will be described.

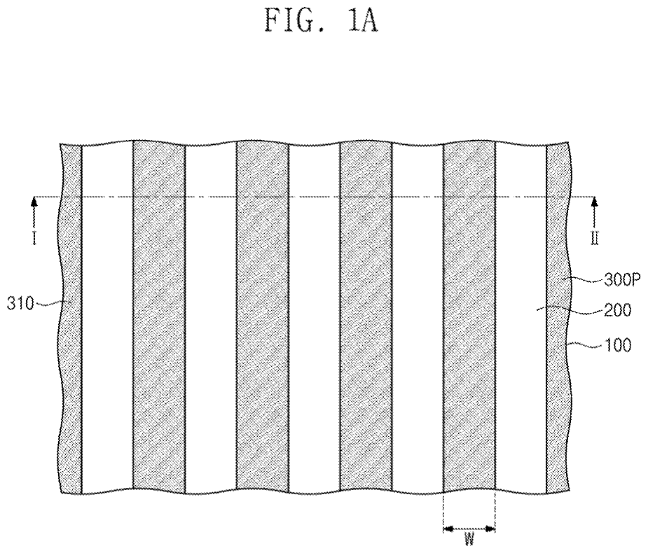

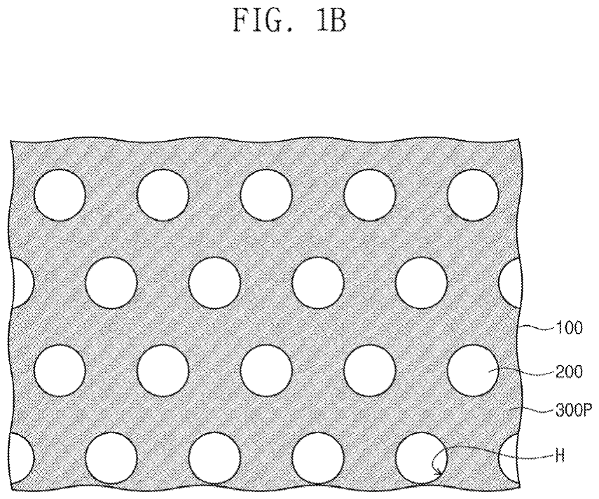

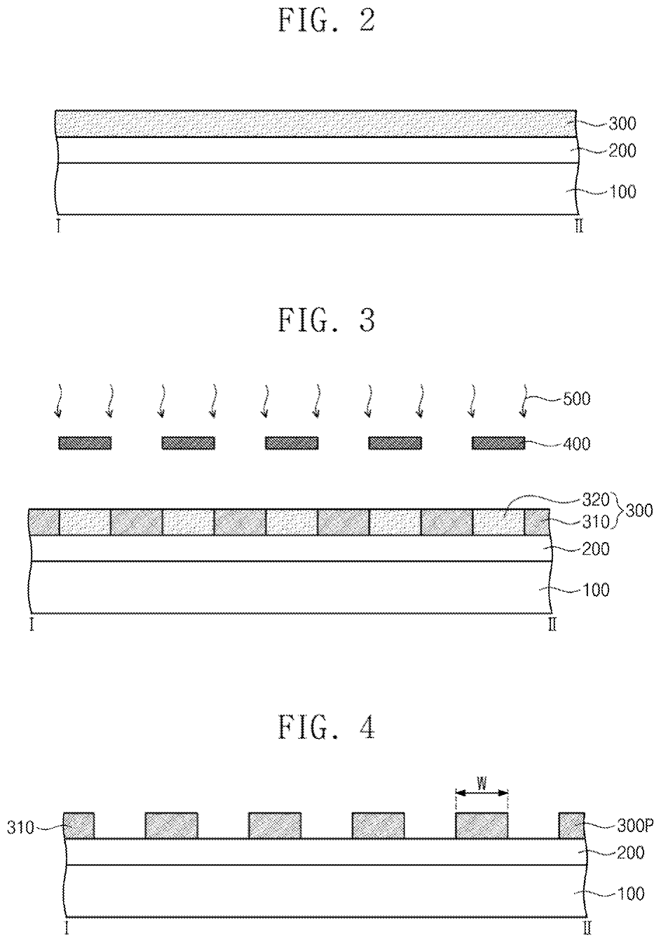

FIG. 1A is a plan view illustrating a resist pattern according to embodiments. FIG. 1B is a plan view illustrating a resist pattern according to embodiments. FIGS. 2 to 6 are views of stages in a method of manufacturing a semiconductor device according to embodiments, and correspond to cross-sections taken along line I-II of FIG. 1A.

Referring to FIGS. 1A and 2, a substrate 100 may be prepared. A lower film 200 and a resist film 300 may be sequentially formed on the substrate 100. The lower film 200 may be an etching target film. The lower film 200 may be formed of a semiconductor material, a conductive material, or an insulating material. The lower film 200 may be formed of a single film or may be a plurality of stacked films. In an implementation, layers may be further provided between the substrate 100 and the lower film 200.

A resist composition according to embodiments may be applied onto the lower film 200 to form the resist film 300. The resist composition may be applied by spin coating. A heat treatment process may be further performed on the applied resist compound. The heat treatment process may correspond to a baking process of the resist film 300.

Referring to FIGS. 1A and 3, the resist film 300 may be exposed by light (e.g., electromagnetic radiation or other energy) 500. The light 500 may be an electron beam or extreme ultraviolet light. Before irradiation of the light 500, a photo mask 400 may be disposed on the resist film 300. The light 500 may be irradiated on a first portion 310 of the resist film 300 exposed by the photo mask 400.

When the light 500 is exposed to the resist film 300, as described above, a polymer may absorb photons of light to emit electrons and hydrogen ions. The polymer may be deprotected by the generated electrons or hydrogen ions to form a polymer having a modified structure. A photosensitizer may generate secondary electrons and hydrogen ions. The resist composition may include the photosensitizer to help improve the deprotection reaction efficiency of the polymer, and to form a polymer having a modified structure with higher efficiency. The first portion 310 of the resist film 300 may be formed quickly, and the first portion 310 or a second portion 320 of the resist film 300 may be formed with improved line width roughness.

The second portion 320 of the resist film 300 may not be exposed to the light 500. The chemical structure of the resist compound in the second portion 320 of the resist film 300 may not be changed. In an implementation, after irradiation of the light 500 is completed, the material of the first portion 310 of the resist film 300 may have a different chemical structure from that of the second portion 320. When secondary electrons or hydrogen ions generated in the first portion 310 of the resist film 300 move to the second portion 320, the polymer structure of the second portion 320 may be changed. In an implementation, a quencher may help prevent secondary electrons or hydrogen ions generated in the first portion 310 from moving to or affecting the second portion 320. The first portion 310 and the second portion 320 of the resist film 300 may be formed at a desired position with high accuracy. Thereafter, the photo mask 400 may be removed.

Referring to FIGS. 1A and 4, the second portion 320 of the resist film 300 may be removed by a developer to form a resist pattern 300P. The second portion 320 of the resist film 300 may be reactive with (e.g., soluble in) the developer, and the first portion 310 of the resist film 300 may not be reactive with the developer. The second portion 320 of the resist film 300 may be selectively removed. The resist pattern 300P may correspond to the first portion 310 of the resist film 300. The resist pattern 300P may expose the lower film 200. Extreme ultraviolet has high energy per photon, so that the resist pattern 300P may be formed with a fine width (W) and pitch. The resist pattern 300P may have improved line width roughness.

The resist pattern 300P may be formed by a patterning process including an exposure and development process of the resist film 300.

In an implementation, as shown in FIG. 1A, the resist pattern 300P may have a linear planar shape. In an implementation, the resist pattern 300P may include portions extending (e.g., lengthwise) in one direction. The planar shape of the resist pattern 300P may be variously modified.

In an implementation, referring to FIG. 1B, the resist pattern 300P may have a plurality of holes H, and each of the holes H may have a circular shape. The holes H of the resist pattern 300P may be arranged in a honeycomb shape. In an implementation, the resist pattern 300P may be variously modified such as a zigzag shape, a polygon, or a circle.

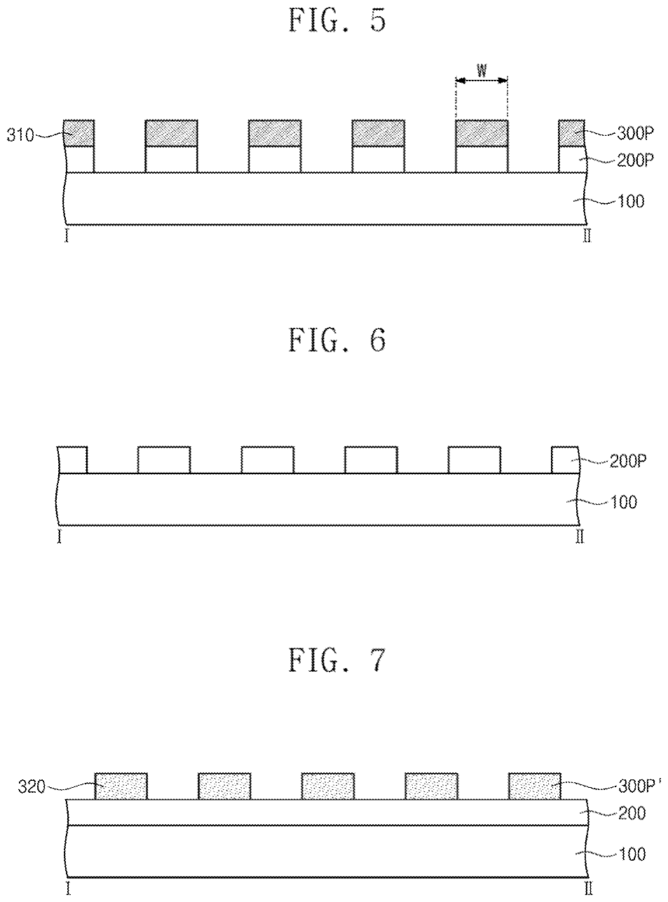

Referring to FIGS. 1A and 5, the lower film 200 exposed by the resist pattern 300P may be removed to form a lower pattern 200P. The removal of the lower film 200 may be performed by an etching process. The lower film 200 may have etching selectivity for or with respect to the resist pattern 300P. The lower pattern 200P may expose the substrate 100. In an implementation, the lower pattern 200P may expose another layer between the substrate 100 and the lower pattern 200P. The width of the lower pattern 200P may correspond to the width W of the resist pattern 300P. The resist pattern 300P may have a narrow width W, and the lower pattern 200P may be formed with a narrow width. The resist pattern 300P may have improved line width roughness, and the width uniformity of the lower pattern 200P may be improved. The resist pattern 300P may be formed at a desired position with high accuracy, and patterning accuracy of the lower pattern 200P may be improved.

Referring to FIGS. 1A and 6, the resist pattern 300P may be removed. Accordingly, forming a pattern may be completed. The pattern may mean the lower pattern 200P. Patterning of the lower film 200 and forming the lower pattern 200P may be completed by the preparation examples described above.

In an implementation, the lower pattern 200P may be a component of a semiconductor device. In an implementation, the lower pattern 200P may be a semiconductor pattern, a conductive pattern, or an insulating pattern in a semiconductor device.

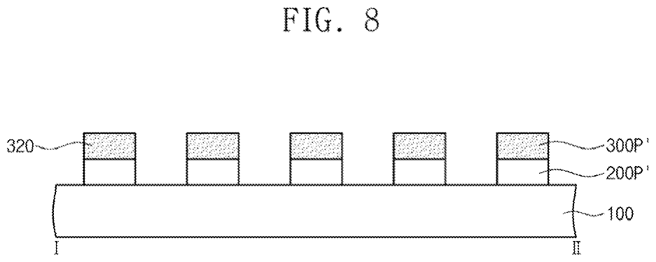

FIGS. 7 and 8 are views of stages in a method of manufacturing a semiconductor device according to other embodiments.

Referring to FIG. 2, a resist film 300 and a lower film 200 may be formed on a substrate 100.

Referring to FIG. 3, irradiation of light 500 may be applied onto a first portion 310 of the resist film 300. After the irradiation of the light 500 is completed, the material of the first portion 310 of the resist film 300 may have a different chemical structure from that of a second portion 320.

Referring to FIG. 7, the first portion 310 of the resist film 300 may be removed by a developer to form a resist pattern 300P′. The second portion 320 of the resist film 300 may not be removed by the developer. The resist pattern 300P′ may correspond to the second portion 320 of the resist film 300.

Referring to FIG. 8, the lower film 200 may be etched to form a lower pattern 200P′. The lower pattern 200P′ may be formed at a position corresponding to the second portion 320 of the resist pattern 300P′. The etching of the lower film 200 may be performed by the substantially same method as that of FIG. 5. Thereafter, the resist pattern 300P′ may be removed.

According to an embodiment, a composition may include a photosensitizer, and a resist pattern may be formed using the composition. Accordingly, manufacturing process efficiency of the resist pattern may be improved. Line width uniformity, precision, and accuracy of the resist pattern may be improved.

One or more embodiments may provide an extreme ultraviolet photoresist composition.

One or more embodiments may provide a resist composition exhibiting improved reaction efficiency in an exposure process.

One or more embodiments may provide a method of forming a pattern having improved line-width uniformity.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, or elements described in connection with a particular embodiment may be used singly or in combination with features, characteristics, or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A resist composition, comprising:
a polymer;
a photoacid generator; and
a material represented by Formula 1: 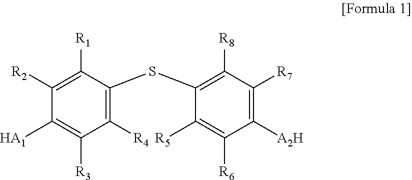
wherein in Formula 1,
R₁, R₂, R₃, R₄, R₅, R₆, R₇, and R₈ are each independently hydrogen, a halogen, a substituted or unsubstituted alkyl group having 1 to 7 carbon atoms, a substituted or unsubstituted carbonyl group having 1 to 7 carbon atoms, a substituted or unsubstituted ester group having 1 to 7 carbon atoms, a substituted or unsubstituted acetal group having 1 to 7 carbon atoms, a substituted or unsubstituted alkoxy group having 1 to 7 carbon atoms, or a substituted or unsubstituted ether group having 1 to 7 carbon atoms, and
A₁ and A₂ are each independently O or S.

2. The resist composition as claimed in claim 1, wherein in Formula 1, A₁ and A₂ are O.

3. The resist composition as claimed in claim 1, wherein the material represented by Formula 1 has a HOMO energy level higher than that of the polymer.

4. The resist composition as claimed in claim 3, wherein the HOMO energy level of the material represented by Formula 1 is higher than −8.50 eV.

5. The resist composition as claimed in claim 1, wherein the material represented by Formula 1 is a material represented by Formula 1-1:

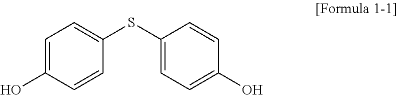 [SMILES: Oc1ccc(Sc2ccc(O)cc2)cc1]

6. The resist composition as claimed in claim 1, wherein:
the material represented by Formula 1 is a material represented by Formula 1-2: 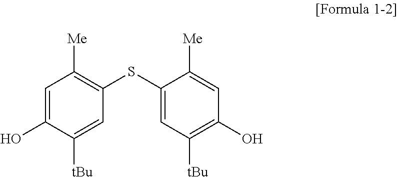 [SMILES: Cc1cc(O)c(C(C)(C)C)cc1Sc1cc(C(C)(C)C)c(O)cc1C]
in Formula 1-2, Me is a methyl group and tBu is a tert-butyl group.

7. The resist composition as claimed in claim 1, wherein:
the material represented by Formula 1 is a material represented by Formula 1-3: 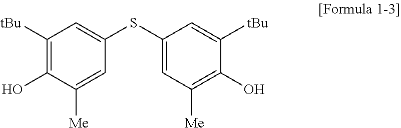 [SMILES: Cc1cc(Sc2cc(C)c(O)c(C(C)(C)C)c2)cc(C(C)(C)C)c1O]
in Formula 1-3, Me is a methyl group and tBu is a tert-butyl group.

8. The resist composition as claimed in claim 1, wherein:
the material represented by Formula 1 is a material represented by Formula 1-4: 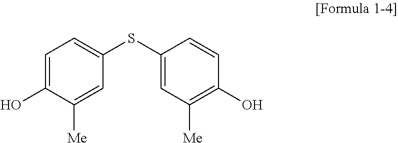 [SMILES: Cc1cc(Sc2ccc(O)c(C)c2)ccc1O]
in Formula 1-4, Me is a methyl group.

9. The resist composition as claimed in claim 1, further comprising a quencher.

10. The resist composition as claimed in claim 1, wherein:
the polymer includes a polymerized unit represented by Formula 2A and a polymerized unit represented by Formula 2B, 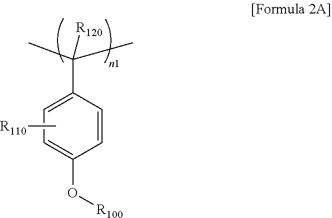
in Formula 2A,
R₁₀₀, R₁₁₀, and R₁₂₀ are each independently hydrogen or a substituted or unsubstituted alkyl group having 1 to 7 carbon atoms, and
n1 is an integer of 1 to 1,000,000, 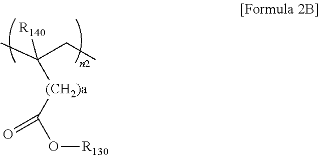
in Formula 2B,
R₁₃₀ is a substituted or unsubstituted tertiary alkyl group having 4 to 20 carbon atoms,
R₁₄₀ is hydrogen or a substituted or unsubstituted alkyl group having 1 to 7 carbon atoms,
a is an integer of 0 to 5, and
n2 is an integer of 1 to 1,000,000, and
n1+n2 is an integer of 50 to 1,000,001.

11. The resist composition as claimed in claim 1, wherein:
the photoacid generator includes a material represented by Formula 3 or Formula 4, 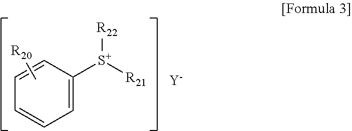
in Formula 3,
R₂₀ is hydrogen or a substituted or unsubstituted alkyl group having 1 to 5 carbon atoms,
R₂₁ and R₂₂ are each independently an alkyl group having 1 to 7 carbon atoms or a substituted or unsubstituted aromatic ring compound having 4 to 20 carbon atoms, and
Y is a sulfonate moiety having 1 to 10 carbon atoms, 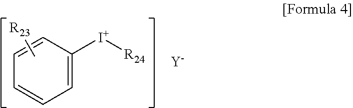
in Formula 4,
R₂₃ is hydrogen or a substituted or unsubstituted alkyl group having 1 to 5 carbon atoms,
R₂₄ is an alkyl group having 1 to 7 carbon atoms or a substituted or unsubstituted aromatic ring compound having 4 to 20 carbon atoms, and
Y is a sulfonate moiety having 1 to 10 carbon atoms.

12. A composition, comprising:
a polymer;
a photoacid generator;
a quencher; and
a material represented by Formula 1A: 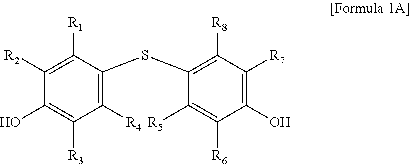
wherein, in Formula 1A, R₁, R₂, R₃, R₄, R₅, R₆, R₇, and R₈ are each independently hydrogen, a halogen, a substituted or unsubstituted alkyl group having 1 to 7 carbon atoms, a substituted or unsubstituted carbonyl group having 1 to 7 carbon atoms, a substituted or unsubstituted ester group having 1 to 7 carbon atoms, a substituted or unsubstituted acetal group having 1 to 7 carbon atoms, a substituted or unsubstituted alkoxy group having 1 to 7 carbon atoms, or a substituted or unsubstituted ether group having 1 to 7 carbon atoms.

13. The composition as claimed in claim 12, wherein the material represented by Formula 1A has a HOMO energy level higher than that of the polymer.

14. The composition as claimed in claim 12, wherein, in Formula 1A, R₁, R₂, R₃, R₄, R₅, R₆, R₇, and R₈ are each independently hydrogen, a halogen, or a substituted or unsubstituted alkyl group having 1 to 7 carbon atoms.

15. The composition as claimed in claim 14, wherein, in Formula 1A, the halogen is fluorine or iodine.

16. The composition as claimed in claim 12, wherein:
the polymer includes a polymerized unit represented by Formula 2A and a polymerized unit represented by Formula 2B: 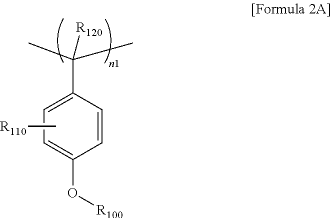
in Formula 2A,
R₁₀₀, R₁₁₀, and R₁₂₀ are each independently hydrogen or a substituted or unsubstituted alkyl group having 1 to 7 carbon atoms, and
n1 is an integer of 1 to 1,000,000, 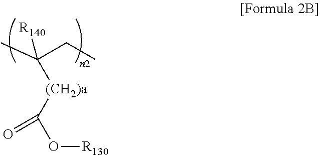
in Formula 2B,
R₁₃₀ is a substituted or unsubstituted tertiary alkyl group having 4 to 20 carbon atoms,
R₁₄₀ is hydrogen or a substituted or unsubstituted alkyl group having 1 to 7 carbon atoms,
a is an integer of 0 to 5, and
n2 is an integer of 1 to 1,000,000, and
n1+n2 is an integer of 50 to 1,000,001.

17. The composition as claimed in claim 16, wherein the material represented by Formula 1A has a higher HOMO energy level than the polymerized unit represented by Formula 2A.

18. A composition, comprising:
a polymer;
a photoacid generator;
a quencher; and
a material represented by Formula A, 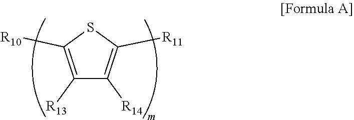
wherein, in Formula A,
R₁₀ and R₁₁ are each independently hydrogen, a halogen, a substituted or unsubstituted alkyl group having 1 to 5 carbon atoms, a substituted or unsubstituted cyclic compound having 5 to 10 carbon atoms, a substituted or unsubstituted carbonyl group having 1 to 5 carbon atoms, a substituted or unsubstituted ester groups having 1 to 5 carbon atoms, a substituted or unsubstituted acetal groups having 1 to 5 carbon atoms, a substituted or unsubstituted alkoxy groups having 1 to 5 carbon atoms, a substituted or unsubstituted ether group having 1 to 5 carbon atoms, —SO₃H, or —NO₂,
R₁₃ and R₁₄ are each independently hydrogen, a halogen, a substituted or unsubstituted alkyl group having 1 to 5 carbon atoms, a substituted or unsubstituted cyclic compound having 5 to 10 carbon atoms, —SO₃H, or —NO₂, R₁₃ and R₁₄ being separate or bonded to each other to form a ring, and
m is an integer of 1 to 5.

19. The composition as claimed in claim 18, wherein the material represented by Formula A is a material represented by one of the following Formulae A-1, A-2, or A-3,

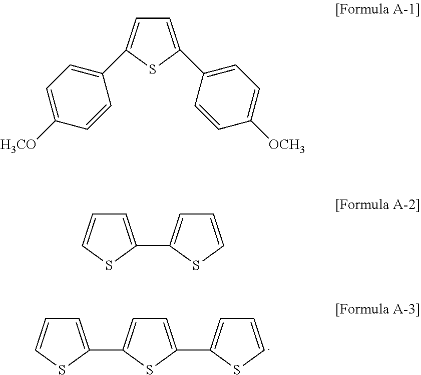 [SMILES: COc1ccc(-c2ccc(-c3ccc(OC)cc3)s2)cc1 ; c1csc(-c2cccs2)c1 ; c1csc(-c2ccc(-c3cccs3)s2)c1]

20. The composition as claimed in claim 18, wherein the material represented by Formula A is a material represented by one of the following Formulae A-5, A-6, A-7, A-8, A-9, A-10, A-11, A-12, A-13 or A-14, [chemical structure]
